(19) United States
(12) Patent Application Publication
(10) Pub. No.: US 2008/0069273 A1
(43) Pub. Date: Mar. 20, 2008

(54) System for Compensating Turbodecoder Phase Shift

(76) Inventors: Benoit Geller, Paris (FR); Jean-Pierre Barbot, Moulineaux (FR); Jean-Marc Brossier, Saint Martin D'Heres (FR); Christophe Vanstraceele, Besancon (FR)

Correspondence Address: YOUNG & THOMPSON, 745 SOUTH 23RD STREET, 2ND FLOOR, ARLINGTON, VA, 22202, US

(21) Appl. No.: 11/628,845

(22) PCT Filed: Jun. 1, 2005
(86) PCT No.: PCT/FR05/01350

§ 371 Date: Jul. 30, 2007

(30) Foreign Application Priority Data
Jun. 10, 2004 (FR) 04 06290

(51) Int. Cl. H03D 1/00

(52) U.S. Cl. 375/341; 375/340

(57) ABSTRACT

A turbocode receiver system of a signal emitted by a turbo-coded modulated transmitter system, includes: a soft demapper (1) the output of which is connected to a turbodecoder (2), and an adaptive locked loop including: a measurement generator (3) the input of which is connected to the turbodecoder output to receive the reliability vector (LLRₒᵤₜ) of the result and adapted to transform the vector into a reliability measurement (M(I)), equal to the average of the lowest reliability values of word bits, transmitted to a phase shift estimator (4) the output of which is connected to a phase compensator (5) positioned upstream of the soft demapper and adapted to correct the incoming signal of the phase value φ.

The present invention relates to a system and a method for compensating block turbodecoder phase shift.

Turbocodes are currently considered to be the most effective coding schemes for forward error correction (FEC).

The turbocode principle was presented for the first time at the Geneva ICC'93 Conference by C. Berrou, A. Glavieux and Thitimajshima. This document presents an iterative decoding of two convolutional codes concatenated in parallel through a non-uniform interleaver. The decoding is carried out by an SISO (soft input/soft output) decoder based on an MAP (maximum a posteriori) algorithm.

In 1993, EP 0 654 910, granted to France Télécom and incorporated herewith by reference, described a turbocode based on block codes. This turbocode uses iterative decoding of two BCH (Bosc-Hacquengheim-Chaudhuri) codes concatenated in series through a uniform interleaver. The decoding uses a new SISO decoder adapted to block codes. This decoding algorithm is known as a Pyndiah algorithm.

Turbocodes have notable performance levels, close to Shannon's theoretical limit.

However, they require optimum reception synchronization, and this is not realistic in the case of signals having a low signal-to-noise ratio, the favored field of use of these decoding algorithms.

Oh and Cheun (“Joint Decoding and Carrier Phase Recovery Algorithm for Turbo Codes”, Wangrok Oh and Kyungwhoon Cheun, IEEE Communications Letters, Vol. 5, No. 9, September 2001, p. 375) noted that a phase error leads to deterioration of the bit error rate (BER).

Oh and Chung also describe, in this document, an adaptive servo loop device allowing the phase shift to be compensated at the decoder. This compensation is calculated from the estimated power of the intrinsic values of the decoder or from the estimated power of the logarithmic likelihood ratios at the output of the second decoder.

Although Oh and Chung give the example of convolutional turbodecoding, the problem also exists for block turbocodes and, in particular, for the Pyndiah decoder.

The object of the invention is therefore to obtain a phase shift-resistant block turbodecoder.

The invention therefore relates to a turbocode receiver system for a signal emitted by a transmitter system, this signal being subjected by the transmitter to turbocoding and to a digital modulation, wherein said system comprises
a soft demapper capable of receiving the modulated signal and of converting it into a sequence of words, each word being composed of n bits and each bit being associated to a reliability value of the value of the bit, the output of which is connected to
a turbodecoder capable of generating a list of words corresponding to the decoded digital data as well as a reliability vector (LLRₒᵤₜ) of the result associated with each word and comprising the reliability value of each word bit, this turbodecoder being a block turbodecoder comprising an iterative SISO decoder such that the input (Rₘ) of the SISO decoder is equal to the vector (R) of the reliability values at the output of the soft demapper plus the product of a coefficient (α) and the difference between the output (R′ₘ) of the SISO decoder at the preceding iteration and said vector (R) of the reliability values at the output of the soft demapper,

and also comprising an adaptive servo loop comprising
a measurement generator, the input of which is connected to the output of the turbodecoder in order to receive the reliability vector (LLRₒᵤₜ) of the result and is capable of transforming this vector into a reliability measurement (M(I)), equal to the average of the lowest reliability values of the word bits, transmitted to
a phase shift estimator capable of calculating the difference between the phase corresponding to the received reliability measurement (M(I)) and the phase corresponding to the maximum of this measurement, the output of which is connected to
a phase compensator positioned upstream of the soft demapper and capable of correcting the incoming signal of the phase value (φ) calculated by the estimator.

According to particular embodiments, the system comprises one or more of the following characteristics:
the reliability measurement (M(I)) is equal to the average of the reliability values substantially below a given value,
the phase shift estimator estimates the phase shift by assuming that the reliability measurement (M(I)) is a parabolic function of the phase shift,
the phase shift estimator estimates the phase shift as the sum of the estimation (φ₀) for the preceding code word and of a weighted constant (Δφ), a calculation interval being defined as having as its center the estimation (φ₀) for the preceding code word and as its half-width the constant (Δφ), and the weighting of the constant being the ratio between the difference between the reliability values (M(φ₁), M(φ₂)) at the ends of the calculation interval and four times the reliability value M(φ₀) at the preceding estimation less twice the sum of the reliability values (M(φ₁), M(φ₂)) at the ends of the calculation interval,
the modulation is a QAM modulation,
a descrambler or a de-interleaver is inserted between the soft demapper and the turbodecoder,
the system for transmitting a binary digital data stream comprises a receiver system,
a scrambler or an interleaver is inserted between the channel coder and the modulator and a descrambler, or a de-interleaver, is inserted between the soft demapper and the turbodecoder.

The invention also relates to a method for receiving a turbocoded and modulated digital signal, including the following steps:

a) receiving of an element of the constellation of the modulation,

b) soft demapping of this element to obtain a word of n bits, each bit being associated with a reliability value of the value of this bit,

c) turbodecoding of this word of n bits providing another word corresponding to the decoded digital data and also a reliability vector of this result comprising the reliability value of each word bit, this turbodecoding being a block turbodecoding comprising an iterative SISO decoding such that the input of the SISO decoding is equal to the vector of the reliability values at the output of the soft demapping plus the product of a coefficient and the difference between the output of the SISO decoding at the preceding iteration and said vector of the reliability values at the output of the soft demapping,

d) calculation of a reliability measurement equal to the average of the lowest reliability values of the word bits,

e) estimation of the phase shift by calculation of the difference between the phase corresponding to the received reliability measurement and the phase corresponding to the maximum of this measurement,

f) compensation by the phase shift estimated on reception of the modulated signal.
At start-up the estimation of the phase shift scans the space of the phases at a pitch equal to half the width of the lobe of the reliability measurement,
for each word received, steps b) to f) are iterated using, as the phase shift estimation,
the phase shift estimation of the preceding word, then
the phase shift estimation of the preceding word minus a predetermined value, then
the phase shift estimation of the preceding word plus a predetermined value, then,
   the phase shift estimation having been calculated as the sum of the estimation (φ₀) for the preceding code word and a weighted constant (Δφ), a calculation interval being defined as having as its center the estimation (φ₀) for the preceding code word and as its half-width the constant (Δφ), and the weighting of the constant being the ratio between the difference between the reliability values (M(φ₁), M(φ₂)) at the ends of the calculation interval and four times the reliability value M(φ₀) at the preceding estimation less twice the sum of the reliability values (M(φ₁), M(φ₂)) at the ends of the calculation interval, steps b) and c) are carried out to obtain the word corresponding to the decoded digital data.

The invention will be better understood in the light of the following description, given merely by way of example and with reference to the appended drawings, in which:

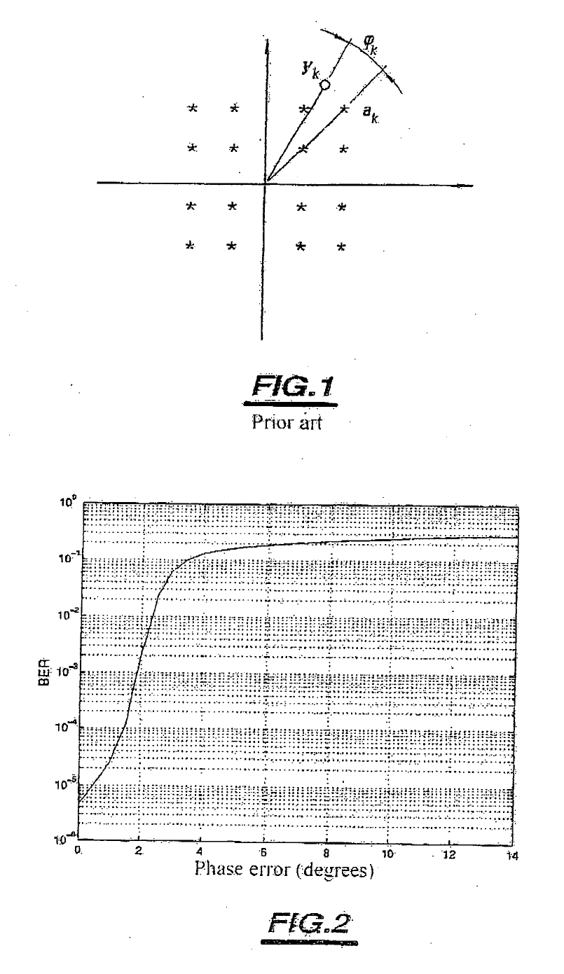

FIG. 1 is an illustration of a constellation of a QAM modulation;

FIG. 2 is an illustration of the variation of the BER as a function of a phase error for a coded signal BCH (32, 26, 4)² over 1024-QAM (Eb/No=19 dB);

FIG. 3 is a block diagram of an implementation of the invention;

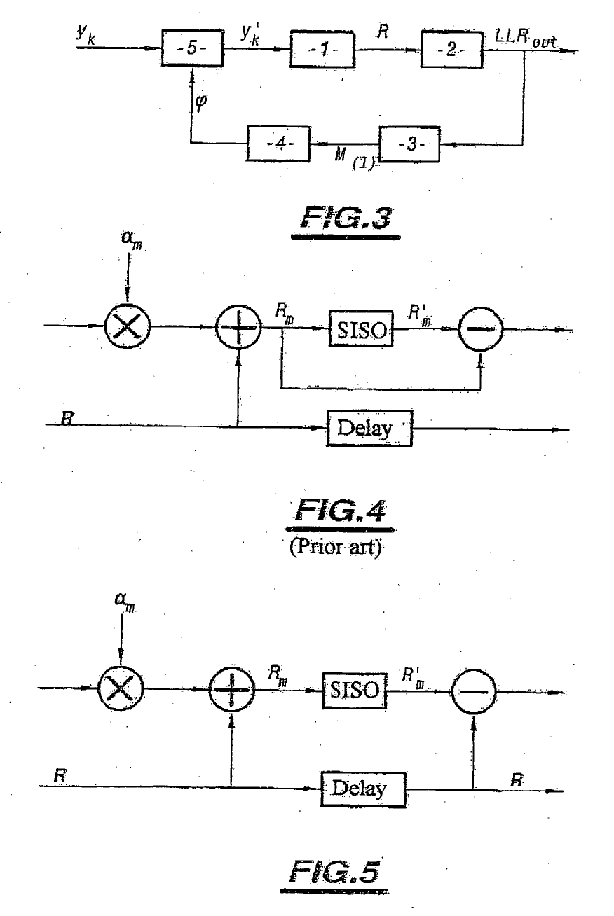

FIG. 4 is a schematic view of the Pyndia turbodecoder according to the prior art;

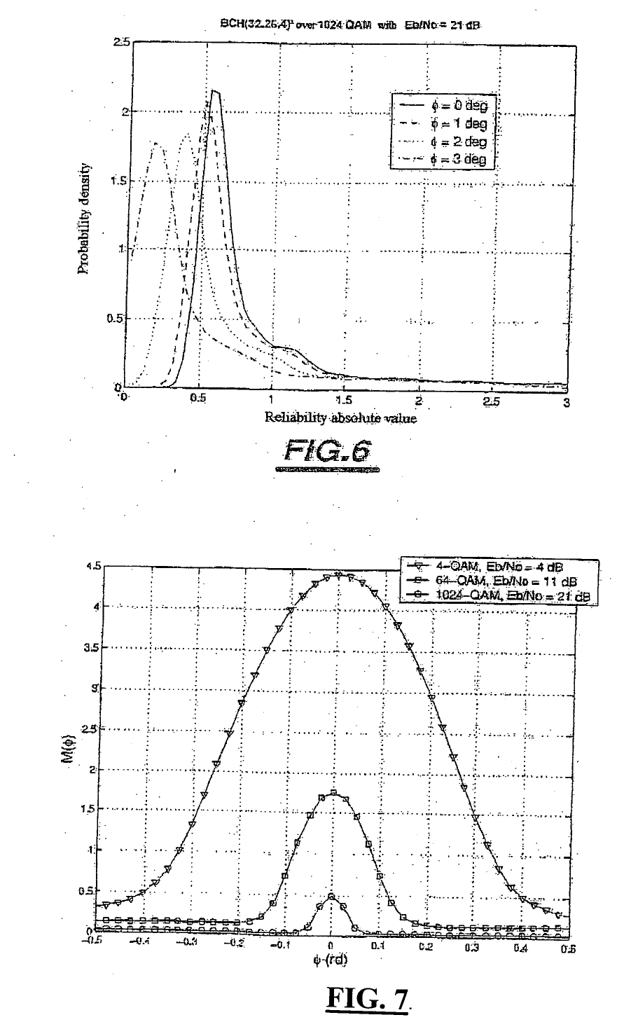

FIG. 5 is a schematic view of the turbodecoder according to an embodiment of the invention;

FIG. 6 is an illustration of the probability distribution of the absolute values of the reliabilities with four half-iterations for a coded signal BCH (32, 26 4)² over 1024-QAM (Eb/No=21 dB), each curve corresponding to a different phase error;

FIG. 7 shows an average of M for 20 code words as a function of the phase error;

FIG. 8 is an operational block diagram of an embodiment of the invention;

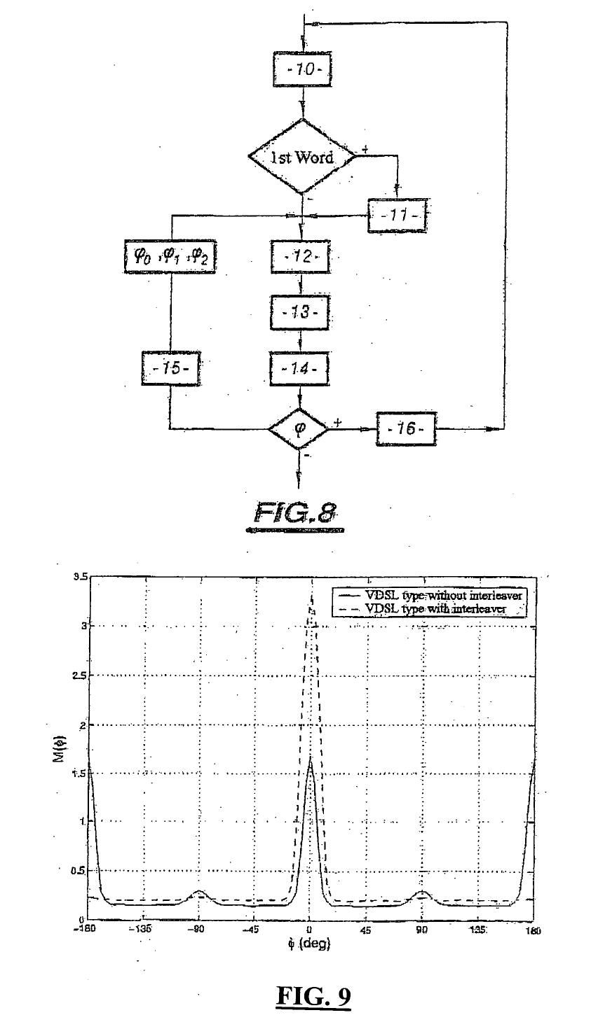

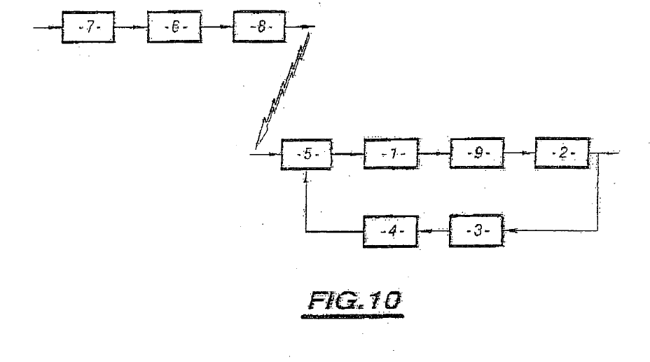

FIG. 9 shows the development of M as a function of the phase error, with and without interleaver; and

FIG. 10 is a schematic view of a coding/decoding system according to another embodiment of the invention.

The purpose of a channel coding is generally to introduce redundancy elements allowing the transmitted data to be reconstructed on reception of said elements, despite the transmission noise. In the example described, the channel coding is a produced code constructed from Hamming BCH codes extended by a parity bit denoted by BCH (32, 26, 4)².

Once the redundancy coding has been carried out, the data is modulated prior to transmission.

Quadrature amplitude modulation (QAM) is a signal modulation method which is currently widely used.

The following description is based on this type of modulation merely by way of example. A person skilled in the art will easily be able to transpose the described embodiment to a different modulation such as phase shift keying (PSK) or minimum shift keying (MSK) modulation.

QAM modulation is a combination of amplitude and phase shift modulation. This modulation consists in distributing the data stream, which is in the form of a stream of bits, into blocks of n bits. There are thus 2ⁿ possible combinations defining a modulation 2ⁿ-QAM. The 2ⁿ words are distributed over all of the amplitude/phase shift combinations defined for modulation. This distribution is often referred to as the QAM constellation. It is thus conventional to represent this distribution in the complex plane, FIG. 1, on which each word aₖ is represented by a point, of which the distance from the origin represents the amplitude, and the angle relative to the x-axis the phase shift.

On reception, given that there is optimum estimation of the sampling moments and that there is only one error on the carrier phase, this error therefore corresponds to a rotation of the QAM constellation by an angle corresponding to this phase shift. It will readily be understood that such rotation can generate an error on the value of the finally detected symbol.

This phase error causes an increase in the binary error rate (BER) (FIG. 2). It will thus be noted that a phase error of two degrees multiplies this error rate by one hundred.

If yₖ is the received symbol and aₖ the transmitted QAM symbol,
yₖ=αₖe^{j}φₖ+nₖ (1)

wherein nₖ is a Gaussian noise and φₖ the phase rotation induced by the error on the carrier phase. φₖ is considered to be a constant during the transmission time of the symbol aₖ. This hypothesis is almost always borne out insofar as the signal jitter may be considered to be a low-frequency disturbance.

The system (FIG. 3) therefore recovers the symbols yₖ at the input of a soft demapper 1.

The soft demapper 1 provides one word per constellation and also a value corresponding to the reliability of the result. In other words, the demapper 1 performs the operation of converting a pair (amplitude, phase shift) into a word of n bits.

However, owing to the noise and the phase rotation, yₖ is in fact at a certain distance from the closest symbol.

Let Λ(eⱼ) be the ratio of log-likelihood, or log-likelihood ratio (LLR), of the bit eⱼ

$$Λ ( {e}_{j} ) = Ln [ \frac{P ( \frac{{e}_{j} = + 1}{R} )}{P ( \frac{{e}_{j} = - 1}{R} )} ] \qquad ( 2 )$$

wherein P{eⱼ=ε/R}, ε=±1 designates the conditional probability that the bit eⱼ corresponds to the mapped value ε, given the received code word R, and Ln designates the Naperian logarithm,

whereas Λ(eⱼ) is positive if the probability that eⱼ is equal to 1 is greater than the probability that eⱼ is equal to 0, and Λ(eⱼ) is negative in the opposite case.

The log-likelihood is conventionally used as the reliability value of the result.

The soft demapper 1 thus provides at its output the vector R of the LLRs of each bit of the demodulated word.

This vector R is provided at the input of the turbodecoder 2 which, using the redundancy created during the channel coding, generates at its output both the decoded word and an LLRₒᵤₜ for estimating the reliability of the result found.

In order to create a servo loop which is adaptive to the phase shift correction, the LLRₒᵤₜs generated by the turbodecoder 2 are introduced as input parameters of a measurement generator 3 which transforms all of the LLRₒᵤₜs into a measurement M^{(I)} representing the reliability of the decoded word I.

As will be explained hereinafter, M^{(I)} is a function dependent on two parameters: the word to be decoded and the phase shift. Its full notation is therefore M(I, φ). However, in order to simplify the notation and to highlight the relevant parameter, the notation M^{(I)} is used when it is the variation of M relative to the words which is considered and M(φ) is used when it is the variation of M relative to the phase shift which is studied.

This measurement is then used by the phase shift estimator 4 to calculate an estimated phase shift φ which is subtracted at 5 from the input signal.

The turbodecoder 2 uses a Pyndiah-type iterative algorithm.

The Pyndiah decoder (FIG. 4) uses an SISO (soft in/soft out) decoding.

It will be recalled that an SISO algorithm is part of the algorithm classes using at the input probabilities on bits (or soft values) to generate other probabilities on the decoded output bits. They differ from hard input (HI) decoder-type algorithms which take hard decisions on the data received, i.e. they fix the value at 0 or 1 as a function of the decoding criteria.

If R(i) is the input of an SISO algorithm and R′(i) its output at the half-iteration I and, as indicated hereinbefore, R is the vector of the LLRs at the output of the soft demapper (and therefore R(1)=R), the input for the next SISO loop i+1 is defined by
R(i+1)=R+α(i)(R′(i)−R(i)) (3)

The system can also modify this algorithm (FIG. 5) so that
R(i+1)=R+α(i)(R′(i)−R) (4)

Thus, the input of the SISO decoder is equal to the vector R of the reliability values at the output of the soft demapper plus the product of a coefficient α and the difference between the output of the SISO decoder at the preceding iteration R′(i) and said vector R of the reliability values at the output of the soft demapper. In this equation, α(i) is an experimentally determined convergence coefficient.

The advantage of this implementation is that it smoothes out the variation of the measurement M^{(I)} and therefore, as will be explained hereinafter, allows the phase shift estimation to be calculated more easily. This smoothing is due to the fact that all of the information provided by the preceding decodings is propagated in the following decodings.

The phase shift of the carrier, as modeled by Equation (1), induces an increase in the Euclidian distance relative to the transmitted word, and therefore a decrease in the reliability values at the output of the turbodecoder, and therefore an increased risk of error.

The Applicant has noted (FIG. 6) that the lowest reliability values are most sensitive to this phenomenon.

For high reliability values, the order of magnitude remains substantially constant regardless of whether or not there is synchronization: some bits will still converge despite poor synchronization.

The lowest reliability values, on the other hand, tend toward zero when the phase shift increases. They are therefore more sensitive to this shift and thus provide more relevant information for the correction of this shift. It will therefore be noted in FIG. 6 that the distribution of the reliability values less than 1.5 is highly dependent on this phase error.

The measurement of this distribution, denoted by M^{(I)}, therefore represents the average of the lowest reliability values at the end of the decoding of the I^{th} received code word:

$$M ( l ) = \frac{1}{n} {\sum }_{k = 1}^{n} \vert {LLRM}_{k}^{( l )} \vert \qquad ( 5 )$$

wherein n is an integer smaller than the length of the code and LLRM^{(I)} is the vector containing the n lowest reliability values of the word in question.

The number n is chosen by a person skilled in the art to provide a compromise between a sufficient number of terms in the average and the disturbance provided by the high reliability values.

An equivalent method of choice is to fix a maximum value beyond which a reliability value is not counted in the average. This eliminates the need to sort the reliability values while preserving the same type of result.

As indicated, this measurement M^{(I)} is introduced into the phase estimator as an input parameter.

The study of the influence of the phase shift φ on the measurement M^{(I)} shows (FIG. 7) that M^{(I)} is at its maximum for a zero phase shift.

Assuming that the conditions are such that the estimator is in its zone of convergence, the maximum value of M^{(I)} may be achieved with a stochastic gradient algorithm.

In this case, the general search algorithm for the phase shift of the carrier is written as follows:

$$\hat{φ} = {\hat{φ}}_{i - 1} + μ ( \begin{matrix}M ( {\hat{φ}}_{i - 1} , {y}_{1} , … , {y}_{k} ) - \\ M ( {\hat{φ}}_{i - 2} , {y}_{1} , … , {y}_{k} )\end{matrix} ) [ sign ( {\hat{φ}}_{i - 2} - {\hat{φ}}_{i - 1} ) ] \qquad ( 6 )$$

wherein, conventionally, the value of the pitch μ is chosen so as to provide a compromise between the mean square error and the rate of convergence.

The value chosen to start the algorithm at each new code word is the value which is estimated for the preceding code word.

However, this algorithm has the drawback of requiring a relatively high number of estimations of M^{(I)}.

A variant of the algorithm requiring less calculating time may be obtained by modeling the variation of M^{(I)} by a single parabola in its cone of convergence.

In this case, three evaluations are sufficient to obtains \hat{φ}.

Given φₒ and a constant Δφ and defining φ₁=φ₀−Δφ et φ₂=φ₀+Δφ, the maximum is then given by:

$$\hat{φ} = {φ}_{0} + Δ φ \frac{M ( {φ}_{2} ) - M ( {φ}_{1} )}{4 M ( {φ}_{0} ) - 2 M ( {φ}_{2} ) - 2 M ( {φ}_{1} )} \qquad ( 7 )$$

Taking for φₒ the value of the estimation for the preceding code word, the phase shift estimation is therefore the sum of the estimation φ₀ for the preceding code word and a constant Δφ, this constant being weighted by the ratio between the difference between the reliability values (M(φ₁), M(φ₂)) at the ends of the calculation interval and four times the reliability value M(φ₀) at the preceding estimation less twice the reliability values at the ends of the calculation interval.

This method therefore allows considerable time savings in terms of criterion evaluation.

However, the parabolic modeling of the variation of M^{(I)} is merely an approximation and is therefore not entirely independent of Δφ. There is thus an optimum value of this parameter for which the estimation will be the best possible.

The Applicant has noted that, under its experimental conditions, an optimum estimation is obtained for Δφ equal to 20% of the width of the lobe of the curve M(φ).

The system thus described operates in the following manner (FIG. 8)

The system receives a word at stage 10.

At start-up, i.e. at the first word received, the system scans at 11 the interval [−π, +π] of the phase shift space, with a pitch corresponding to half the width of the lobe, said width having been determined beforehand, so as to determine an initial phase shift estimation φ₀.

Then, for each word, the system performs
a first iteration with a phase shift correction of φ₀ at 12. The term “iteration” refers to the successive steps of phase shift correction, at 12, of soft demapping, at 13, turbodecoding, at 14, calculation of the measurement M at 15. Then,
a second iteration with a phase shift correction of φ₁=φ₀−Δφ and
a third iteration with φ₂=φ₀+Δφ.

As φ₀, φ₁ et φ₂ and also M(φ₀), M(φ₁) and M(φ₂) are known, and using Equation (7), the system deduces therefrom the estimation φ of the phase shift and then launches the last iteration for this word in order to obtain the decoded word at 16 before looping back to the following word.

It should be noted that during the search and phase shift calculation iterations, the turbodecoder is able to limit the number of internal iterations that it performs. The reliability values used, and therefore M(I), converge very rapidly after a few (approximately four) half-iterations.

The device thus described therefore allows the phase shift to be easily cancelled out or reduced to the extent that it has merely a limited influence on the reliability of the decoding results.

Nevertheless, for certain types of QAM source coding, the device thus described preserves a phase ambiguity at πrd or

$$\frac{π}{2} r d .$$

This occurs when the labeling used is symmetrical at πrd or

$$\frac{π}{2} r d .$$

For example, when the labeling, i.e. the representation of the symbols, used is that of the VDSL standard (FIG. 9), two points of symmetry relative to the center, of the constellation are in this case labeled by two complementary binary sequences. Rotation of π thus causes all of the bits of the code word to be inverted. Now, as the complement of an extended BCH code word also pertains to this code, the result obtained at the output of the device is a reliability value of equal importance as for the original word received without rotation.

Unless an appropriate measure is taken, this may cause, during start-up of the device, when the device seeks the initial shift, the shift fact to be locked to a shift value of within π.

A first solution consists in choosing a labeling not having these symmetries such as, for example, quasi-Gray labeling.

However, this solution is not always possible since, for example, the type of labeling is already chosen in the standard.

Accordingly, the Applicant proposes a second solution which has the advantage of being more general and more effective.

This second solution consists (FIG. 10) in interposing a one code word seized scrambler 6, between the channel coding 7 and the mapping operation 8 at the transmitter. An inverse descrambling operation is then carried out at the receiver by interposition of a descrambler 9 between the soft demapper 1 and the turbodecoder 2.

This second solution also has the advantage of strongly attenuating the local extremes present at

$$- \frac{π}{2} and \frac{π}{2} ,$$

as shown in FIG. 9.

The scrambler/descrambler pair can be replaced by an interleaver/de-interleaver pair or any other equivalent system, the purpose of which is to break the symmetry of the channel coding.

The particularly advantageous results of the device described were validated by the carried out experiments and simulations.

There is thus obtained in a particularly advantageous manner a phase compensation device which allows turbodecoding under optimum conditions.

Moreover, as the operations performed are relatively simple, this device may be constructed at low cost in terms of computational power or working memory capacity.

1. A turbocode receiver system for a signal emitted by a transmitter system, the said signal being subjected by the transmitter to turbocoding and to a digital modulation wherein said system comprises
a soft demapper (1) capable of receiving the modulated signal and of converting it into a sequence of words, each word being composed of n bits and each bit being associated to a reliability value of the value of the bit, the output of which is connected to
a turbodecoder (2) capable of generating a list of words corresponding to the decoded digital data as well as a reliability vector (LLR_{Out}) of the result associated with each word and comprising the reliability value of each word bit, this turbodecoder (2) being a block turbodecoder comprising an iterative SISO decoder such that the input (Rₘ) of the SISO decoder is equal to the vector (R) of the reliability values at the output of the soft demapper plus the product of a coefficient (α) and the difference between the output (R′ₘ) of the SISO decoder at the preceding iteration and said vector (R) of the reliability values at the output of the soft demapper,
and also comprising an adaptive servo loop comprising
a measurement generator (3), the input of which is connected to the output of the turbodecoder in order to receive the reliability vector (LLR_{OUT}) of the result and is capable of transforming this vector into a reliability measurement (M(I)), equal to the average of the lowest reliability values of the word bits, transmitted to
a phase shift estimator (4) capable of calculating the difference between the phase corresponding to the received reliability measurement (M(I)) and the phase corresponding to the maximum of this measurement, the output of which is connected to
a phase compensator (5) positioned upstream of the soft demapper and capable of correcting the incoming signal of the phase value (φ) calculated by the estimator.

2. A turbocode receiver system for a signal emitted by a transmitter system, the said signal being subjected by the transmitter to turbocoding and to a digital modulation, wherein said system comprises
a soft demapper (1) capable of receiving the modulated signal and of converting it into a sequence of words, each word being composed of n bits and each bit being associated to a reliability value of the value of the bit, the output of which is connected to
a turbodecoder (2) capable of generating a list of words corresponding to the decoded digital data as well as a reliability vector (LLR_{OUT}) of the result associated with each word and comprising the reliability value of each word bit, this turbodecoder (2) being a block turbodecoder comprising an iterative SISO decoder,
and also comprising an adaptive servo loop comprising
a measurement generator (3), the input of which is connected to the output of the turbodecoder in order to receive the reliability vector (LLRₒᵤₜ) of the result and is capable of transforming this vector into a reliability measurement (M(I)), equal to the average of the lowest reliability values of the word bits, transmitted to
a phase shift estimator (4) capable of calculating the difference between the phase corresponding to the received reliability measurement (M(I)) and the phase corresponding to the maximum of this measurement, the output of which is connected to
a phase compensator (5) positioned upstream of the soft demapper and capable of correcting the incoming signal of the phase value (φ) calculated by the estimator.

3. The turbocode receiver system as claimed in claim 1, wherein the reliability measurement (M(I)) is equal to the average of the reliability values substantially below a predetermined value.

4. The turbocode receiver system as claimed in claim 1, wherein the phase shift estimator (4) estimates the phase shift by assuming that the reliability measurement (MQ)) is a parabolic function of the phase shift.

5. The turbocode receiver system as claimed in claim 4, wherein the phase shift estimator (4) estimates the phase shift as the sum of the estimation (φ₀) for the preceding code word and of a weighted constant (Δφ), a calculation interval being defined as having as its center the estimation (φ₀) for the preceding code word and as its half-width the constant (Δφ), and the weighting of the constant being the ratio between the difference between the reliability values (M(φ₁), M(φ₂)) at the ends of the calculation interval and four times the reliability value M(φ₀) at the preceding estimation less twice the sum of the reliability values (M(φ), M(φ₂)) at the ends of the calculation interval.

6. The turbocode receiver system as claimed in claim 1, wherein the modulation is a QAM modulation.

7. The turbocode receiver system as claimed in claim 1, wherein a descrambler (9) or a de-interleaver is inserted between the soft demapper (1) and the turbodecoder (2).

8. A system for transmitting a binary digital data stream, wherein said system comprises a receiver system as claimed in claim 1.

9. The system for transmitting a binary digital data stream as claimed in claim 8, wherein a scrambler (6) or an interleaver is inserted between the channel coder (7) and the modulator (8) and wherein a descrambler (9), or a de-interleaver, is inserted between the soft demapper (1) and the turbodecoder (2).

10. A method for receiving a turbocoded and modulated digital signal, wherein said method includes the following steps:
a) receiving of an element of the constellation of the modulation,
b) soft demapping of this element to obtain a word of n bits, each bit being associated with a reliability value of the value of this bit,
c) turbodecoding of this word of n bits providing another word corresponding to the decoded digital data as well as a reliability vector of this result comprising the reliability value of each word bit, this turbodecoding being a block turbodecoding comprising an iterative SISO decoding such that the input of the SISO decoding is equal to the vector of the reliability values at the output of the soft demapping plus the product of a coefficient and the difference between the output of the SISO decoding at the preceding iteration and said vector of the reliability values at the output of the soft demapping,
d) calculation of a reliability measurement equal to the average of the lowest reliability values of the word bits,
e) estimation of the phase shift by calculation of the difference between the phase corresponding to the received reliability measurement and the phase corresponding to the maximum of this measurement,
f) compensation by the phase shift estimated on reception of the modulated signal.

11. The method for receiving a turbocoded and modulated digital signal as claimed in claim 10, wherein at start-up the estimation of the phase shift scans the space of the phases at a pitch equal to half the width of the lobe of the reliability measurement.

12. The method for receiving a turbocoded and modulated digital signal as claimed in claim 10, wherein for each word received, steps b) to f) are iterated using, as the phase shift estimation,
the phase shift estimation of the preceding word, then
the phase shift estimation of the preceding word minus a predetermined value, then
the phase shift estimation of the preceding word plus a predetermined value, then,
the phase shift estimation having been calculated as the sum of the estimation (φₒ) for the preceding code word and a weighted constant (Δφ), a calculation interval being defined as having as its center the estimation (φₒ) for the preceding code word and as its half-width the constant (Δφ), and the weighting of the constant being the ratio between the difference between the reliability values (M(φ₁), M(φ₂)) at the ends of the calculation interval and four times the reliability value M(φ₀) at the preceding estimation less twice the sum of the reliability values (M(φ₁), M(φ₂)) at the ends of the calculation interval, steps b) and c) are carried out to obtain the word corresponding to the decoded digital data.

13. The method for receiving a turbocoded and modulated digital signal as claimed in claim 11, wherein for each word received, steps b) to f) are iterated using, as the phase shift estimation,
the phase shift estimation of the preceding word, then
the phase shift estimation of the preceding word minus a predetermined value, then
the phase shift estimation of the preceding word plus a predetermined value, then,
the phase shift estimation having been calculated as the sum of the estimation (φₒ) for the preceding code word and a weighted constant (Δφ), a calculation interval being defined as having as its center the estimation (φₒ) for the preceding code word and as its half-width the constant (Δφ), and the weighting of the constant being the ratio between the difference between the reliability values (M(φ₁), M(φ₂)) at the ends of the calculation interval and four times the reliability value M(φ₀) at the preceding estimation less twice the sum of the reliability values (M(φ₁), M(φ₂)) at the ends of the calculation interval, steps b) and c) are carried out to obtain the word corresponding to the decoded digital data.

14. The turbocode receiver system as claimed in claim 2, wherein the reliability measurement (M(I)) is equal to the average of the reliability values substantially below a predetermined value.
